(19) United States
(12) Patent Application Publication
(10) Pub. No.: US 2025/0196227 A1
(43) Pub. Date: Jun. 19, 2025

(54) Hybrid 3D Printed Heat Sink

(71) Applicant: National University of Singapore, Singapore (SG)

(72) Inventors: Wei David WANG, Singapore (SG); Sin Liang SOH, Singapore (SG); Wen Feng LU, Singapore (SG); Matthew Lee Liong LAW, Singapore (SG); Poh Seng LEE, Singapore (SG)

(21) Appl. No.: 18/847,812

(22) PCT Filed: Mar. 17, 2023
(86) PCT No.: PCT/SG2023/050177

§ 371 Date: Sep. 17, 2024

(30) Foreign Application Priority Data
Mar. 18, 2022 (SG) 10202202742X

(51) Int. Cl. B22F 10/28; B33Y 10/00; B33Y 80/00; F28F 3/04

(52) U.S. Cl. CPC B22F 10/28; B33Y 10/00; B33Y 80/00; F28F 3/04; F28F 2255/18

(57) ABSTRACT

The present invention describes heat sinks (100) in which fins (120) are hybrid 3D printed using laser powder-bed fusing (LPBF) or selective laser melting (SLM) (200) of a fin powder (122) deposited directly over a substrate (140). The fin powder (122) forms a powder-bed, which height is increased, layer by layer, and the fins (120) are being built up, layer by layer, by laser melting and fusing the fin powder (122). The fin powder (122) may be copper, copper alloy, aluminium or aluminium alloy, whilst the associated substrate (140) is copper-based or aluminium-based. The substrate (140) is prepared by conventional machining, hence, the process (200) is called hybrid LPBF or SLM. The heat sinks (100) obtained have excellent heat dissipation and temperature stability performances.

### RELATED APPLICATIONS

The present invention claims priority to Singapore patent application Ser. No. 10/202,202742X filed on 18 Mar. 2022, the disclosure of which is incorporated in its entirety.

### FIELD OF INVENTION

The present invention relates to hybrid 3D printing of heat sinks. In particular, fins of the heat sinks are fabricated by 3D-printing using laser powder-bed fusion (LPBF) or more generally called selective laser melting (SLM), with the fins being formed of copper or aluminium.

### BACKGROUND

Heat sinks are used to cool down an electric or electronic component to which the heat sinks are thermally connected to. Conventionally, the heat sinks are formed by extrusion; powder metallurgy; machining, such as EDM; and so on.

Extruded heat sinks have simple fin geometry but the fin dimensions are relatively large; the fin dimensions thus place a limit to the surface area available for heat dissipation. Powder metallurgy, as disclosed in patent publication US20050252637, by Hon Hai Precision Industry Co. Ltd., appears to be suitable to produce heat sinks with finer fin geometries. With needs to improve heat sink performance, attempts have been made to fabricate fins by using electro-discharge machining (EDM); however, EDM is a very slow process; EDM is also fraught with manufacturing limitations in that EDM wires often snap. When the EDM machined fins are attached onto a substrate, the attachment interface causes heat flow resistance from the substrate to the fins.

It can thus be seen that there exists a need for a new method for fabricating heat sinks that provide more effective heat dissipation than conventionally available heat sinks. Preferably, such a method is cost effective and suitable for mass production.

### SUMMARY

The following presents a simplified summary to provide a basic understanding of the present invention. This summary is not an extensive overview of the present invention, and is not intended to identify key features of the invention. Rather, it is to present some of the inventive concepts of this invention in a generalised form as a prelude to the detailed description that is to follow.

The present invention seeks to provide new heat sinks that provide effective heat dissipation and a new process for fabricating these heat sinks. The new process involves hybrid 3D printing of fins of the heat sink by laser powder-bed fusing or selective laser melting of fin powders on a machined substrate. This new process has been tested and the heat sinks obtained have excellent heat dissipation performance.

In one embodiment, the present invention provides a heat sink comprising: a substrate; and a plurality of fins formed directly on the substrate, with a first layer of each fin being formed directly on the substrate using a laser powder-bed fusing (LPBF) or selective laser melting (SLM) process on a fin powder deposited on the substrate, wherein the fins are built up, layer by layer using laser fusion to reach a predetermined height.

Preferably, the fins are made from CuCrZr, copper alloy powder or pure copper powder, whilst the substrate is machined from a copper-based material. In another embodiment, the fins are made from aluminium or aluminium alloy powder, whilst the substrate is machined from an aluminium-based material.

Preferably, the fins have a height: thickness ratio range of substantially 4 to 20, and a height: spacing ratio range of substantially 4 to 35.

Preferably, the fins are configured with a parallelogram cross-sectional shape or geometry. The fins are configured in rows, and a row spacing is substantially equal or greater than an oblique spacing between adjacent fins in a row.

Preferably, threaded holes are provided on the substrate for mounting a protective cover over or around the fins. Holes are also provided also on the substrate to mount the heat sink to a member that requires heat dissipation.

In another embodiment, the present invention provides a LPBF or SLM method for hybrid 3D print fabrication of a heat sink, which comprises: forming a substrate using a conventional subtractive machining; forming a powder-bed of a fin powder over the substrate; operating a laser to melt and to fuse particles of the fin powder to build a first layer of the fins directly on the substrate; and adding the fin powder to increase a height of the powder-bed, layer by layer, operating the laser to build up the fins, layer by layer, until the fins reach a predetermined height.

Preferably, operating the laser to build the fins, layer by layer, comprises generating a pattern of the fin geometry from a CAD or computer system and outputting the pattern to a scanner to direct a laser beam from the laser onto the fin powder. The pattern comprises rows of the fins, with each fin forming a parallelogram shape, and adjacent fins in a row are spaced apart at an oblique side of the parallelogram.

### BRIEF DESCRIPTION OF THE DRAWINGS

This invention will be described by way of non-limiting embodiments of the present invention, with reference to the accompanying drawings, in which:

FIG. 1 illustrates a structure of a conventional heat sink;

FIG. 2 illustrates a plan view of a heat sink obtained according to an embodiment of the present invention; FIG. 3 illustrates a profile of fins of the heat sink shown in FIG. 2, whilst FIG. 4 illustrates a side view of the heat sink and FIG. 5 shows a photograph of part of the heat sink;

FIGS. 6-8 illustrate performances of the above heat sink with a comparative heat sink obtained by EDM wire-cut, whilst FIG. 9 shows thermal properties of a copper-based alloy used in making the above heat sink compared to thermal properties of copper; and

FIG. 10 illustrates a hybrid 3D printing method for fabricating the above heat sink according to another embodiment of the present invention, whilst FIG. 11 illustrates layer-by-layer building up of the above 3D fin printing.

### DETAILED DESCRIPTION

One or more specific and alternative embodiments of the present invention will now be described with reference to the attached drawings. It shall be apparent to one skilled in the art, however, that this invention may be practised without such specific details. Some of the details may not be described at length so as not to obscure the invention.

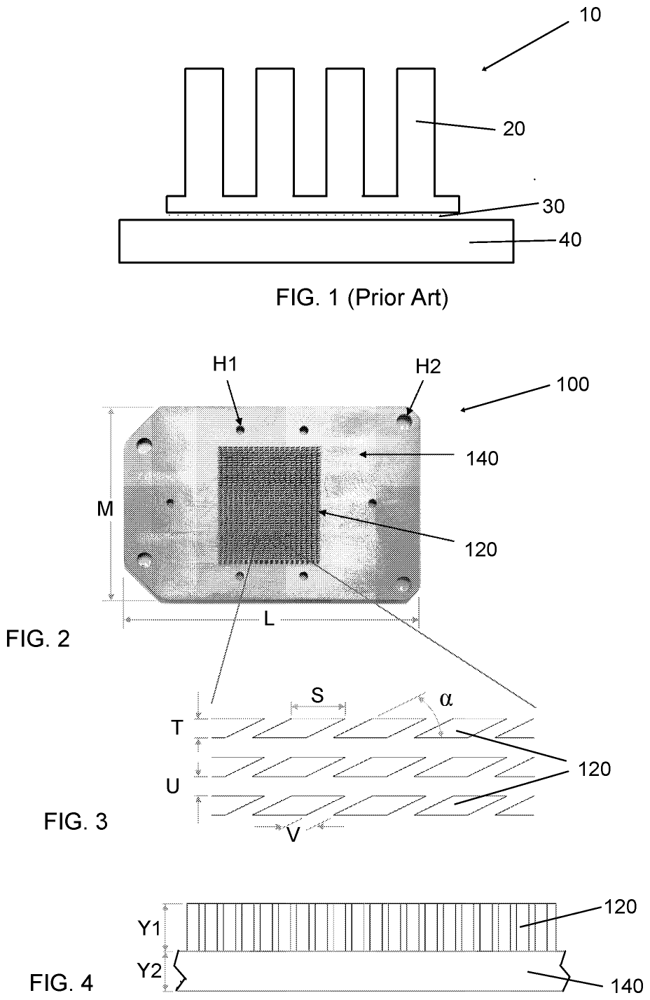

FIG. 1 shows a structure of a conventional heat sink 10. As shown, the conventional heat sink 10 has a plurality of fins 20. The fins 20 are attached onto a substrate 40 via an attachment interface layer 30 (which may constitute a thermal adhesive, epoxy or solder); alternatively, the fins 20 may be attached onto the substrate 40 with mechanical elements, such as screws, but this creates an interface joint. As discussed in the background, the fins 20 have dimensions that are relatively large and the surface area for heat dissipation is thus limited. Even if heat sink with the fins 20 are EDM wire-cut, such EDM wire-cut heat sink now labelled 10a, the attachment interface layer 30 or interface joint causes resistance to heat flow from the substrate 40 to the fins 20.

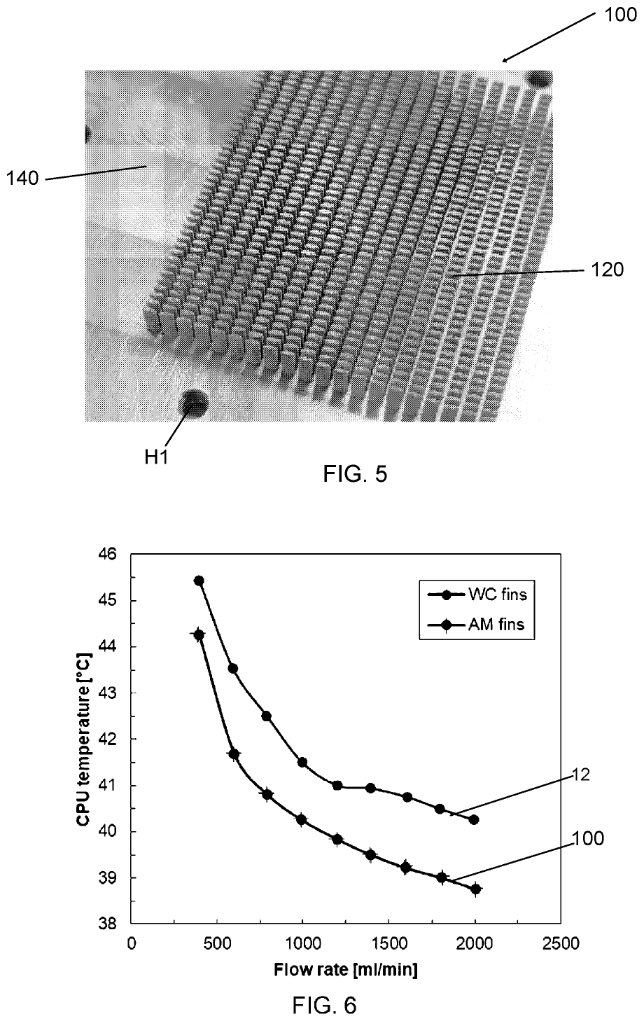

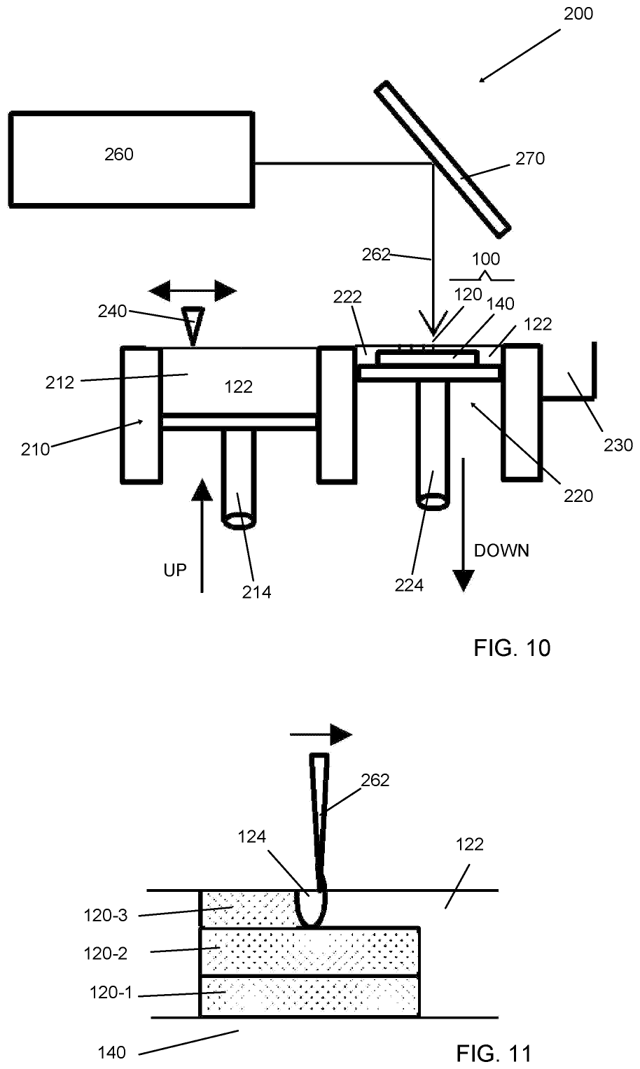

Now, referring to FIGS. 2 and 5, which show a heat sink 100 of the present invention according to one embodiment. As shown, the heat sink 100 is made up of a plurality of fins 120 extending from a substrate 140. In one embodiment, the fins 120 have very fine geometry and are made from a copper alloy powder 122 that is fused and 3D printed to extend directly from a copper-based substrate 140. In one embodiment, the copper alloy powder 122 is composed of CuCrZr, whilst the substrate 140 is a copper-based material, including a copper alloy. In another embodiment, the fins 120 are made from an aluminium or aluminium alloy powder, whilst the substrate 140 is an aluminum-based material. In both embodiments, the fins 120 are 3D printed directly on the substrate 140 by employing laser powder-bed fusion (LPBF) or, more generally, selective laser melting (SLM) 200 using copper, copper alloy, aluminium or aluminium alloy powder 122, whilst the substrate 140 is formed by conventional subtractive machining, such as, milling, grinding, and so on; the heat sink 100 fabrication is thus described as hybrid 3D printing using LPBF or SLM process 200 to form the fins 120 directly on the substrate 140. It is possible to use other types of copper, copper alloy powder, aluminium, aluminium alloy powder, copper-based and aluminium-based substrates that have excellent thermal conductive properties. The LPBF or SLM 200 is shown in FIG. 10 and it will be clearer after describing the heat sink 100 and its heat performance.

As shown in FIG. 2, mounting holes H1,H2 are formed on the substrate 140. Holes H1 (preferably, being threaded) are provided to mount a protective cover around or over the fins 120 when the heat sink 100 is put to use. Holes H2 are provided to mount the heat sink 100 onto an electric or electronic component from which heat is to be dissipated.

FIG. 3 shows an exploded view of the fins 120 as seen from a top view; in other words, FIG. 3 shows outlines of the fins 120 in plan view. In one embodiment, the fins 120 are parallelogram in shape in the plan or cross-sectional view, with a longitudinal dimension S, thickness T, oblique spacing V and oblique angle α; the fins 120 are arranged in linear rows in the longitudinal S direction but the rows are spaced part with dimension U. In one embodiment, dimensions S, T, V and U are substantially 1.4, 0.5, 0.3 and 0.5, respectively. It is possible that dimension S can vary from substantially 1 mm to a few mm, and the oblique angle α can range from about 90 degrees to substantially 10 degrees. The fins 120 dimensions and spacings, or fin geometry, are not numerically limiting but are chosen to depend on a designed heat dissipation performance and/or limitations of the LPBF or SLM process 200.

FIG. 4 shows a height projection of the fins 120 shown in FIG. 3. As shown in FIG. 4, the height of the fins 120 is indicated by Y1, whilst the thickness of the substrate 140 is indicated by Y2. Thickness Y2 may be selected to minimise any warping from flatness after fabrication of the heat sink. Height dimensions Y1, Y2 can range from substantially about 2 mm to about 10 mm, and also depend on the designed heat dissipation performance and/or limitations of the LPBF or SLM process 200. From the above dimensions, the fins 120 can be characterised as having a height: thickness ratio of substantially 4 to 20, and a height: spacing ratio of substantially 4 to 35.

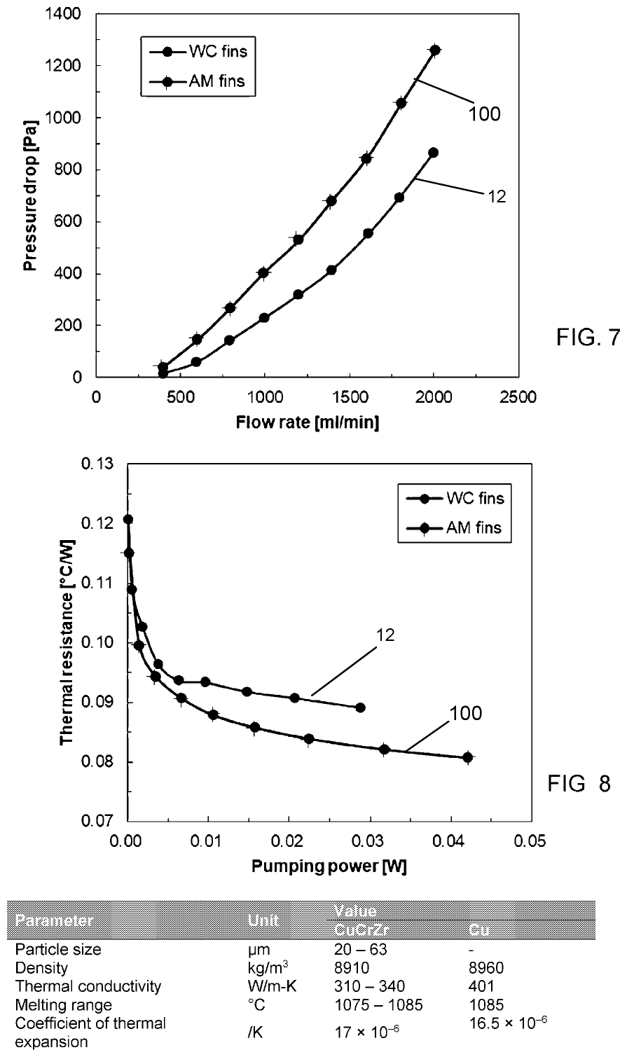

FIGS. 6-8 show heat dissipation and pressure drop performance of the heat sink 100 compared to a comparative heat sink 12 formed entirely by EDM wire-cut. The comparative heat sink 12 is formed from copper with similar fin and substrate geometries as the heat sink 100 of the present invention. In the comparative study, the two heat sinks 12, 100 were separately mounted onto a CPU that was operated at 100% load with various water convection rates. As can be seen from FIG. 6, the hybrid 3D printed heat sink 100 brought the CPU to a lower temperature. However, due to the higher surface roughness of the 3D printed fins 120, the pressure drop of water flowing over the hybrid 3D printed heat sink 100 is higher compared to that over the heat sink 12 as seen from FIG. 7. Nevertheless, the pressure drop penalty incurred with the hybrid 3D printed heat sink 100 was justified due to its better cooling performance. As can be seen in FIG. 8, the hybrid 3D printed heat sink 100 exhibited higher overall performance when evaluated using the thermal resistance vs pumping power characteristic, against the overall performance of the comparative heat sink 12.

FIG. 9 shows some physical properties of the CuCrZr material 122 compared to copper. It is seen that although CuCrZr 122 has a lower thermal conductivity (about 15-23% lower than copper), yet the heat dissipation performance of the heat sink 100 is as effective as the comparative copper heat sink 12. Inventors believe that melting and fusing the fin powder 122 directly on the substrate 140 by the LPBF or SLM process 200 produce continuous material integrity between the substrate 140 and the fins 120. Inventors also believe that the minute sizes of the fin powder 122 (substantial range of about 20-70 μm) allow the fin powders 122 to melt and fuse to build up layer-by-layer with continuous material integrity within each of the fins 120. Continuous material integrity may mean that there are no voids, interfaces or deleterious defects that reduce heat conduction from the substrate 140 to the fins 120 or within the fins 120.

Now, referring to FIG. 10 on a schematic of the LPBF or SLM process 200 according to another embodiment of the present invention. The LPBF or SLM process 200 shown is for illustrating and for describing a method to fabricate the heat sink 100. As illustrated, a machine employing the LPBF or SLM process 200 includes a powder supply station 210 disposed adjacent to a production station 220. The powder supply station 210 has a supply chamber 212, which, in use, is filled with the fin powder 122 and a supply piston 214 is operable to feed the fin powder 122 in an upward, step-wise manner. At the production station 220, the substrate 140 is mounted in a production chamber 222, which is located above a production piston 224; the production piston 224 is operable to move downward in a step-wise manner in coordination with the step-wise movement of the supply piston 214, as the heat sink 100 is being fabricated. A top of both the powder supply station 210 and the production station 220 are aligned with one another. In a preparation process, the supply piston 214 is stepped up and a blade 240 is operated to scrape across the top of the powder supply chamber 212 over to the production chamber 222 to fill void spaces surrounding the substrate 140 mounted in the production chamber 222. The preparation process may be repeated several times until the fin powder 122 is deposited to a predetermined height (for eg., 0.05 mm) over the substrate 140, to form a laser powder bed (LPB) in the production chamber 222; the blade 240 is then brought to a home position towards a far left-hand side of the powder supply station 210. Any excess fin powder 122 is pushed into an overflow chamber 230, located adjacent to the production station 220.

To form the first layer of the fin 120 directly onto the substrate 140, the laser member 260 is turned on, the emitted laser beam 262 is reflected and scanned by a scanner 270 to impinge on the fin powder 122, causing the fin powder 122 to melt and the powder particles to fuse together, as can be seen in FIG. 10. As the laser beam 262 is traversed and controlled by the scanner 270 according to the fin geometry, the melting and fusing of the fin powder 122 forms a first layer of the fins 120 directly on the substrate 140. To form a second layer, the supply piston 214 is stepped up whilst the production piston 224 is stepped down in a coordinated manner, and the blade 240 is then moved to scrape a layer of the fin powder 122 from the supply chamber 212 over to the production chamber 222. The SLM process 200 is continued to build up the fins 120, layer by layer, to the desired height Y1, in a manner similar to 3D additive printing. In another configuration of the LPBF or SLM process 200, it is possible that each layer of the fin 120 be formed by multiple passes of the laser beam 262, and this depends on the size and power of the laser beam 262. In addition, the fin geometry can be generated by a CAD or computer system and the output is linked to the scanner 270, thereby directing the laser beam 262 onto the fin powder 122 and allowing the process 200 to be mechanized or automated.

FIG. 11 shows three layers of the fins 120 as the LPBF or SLM process 200 continues. As shown, the laser beam 262 produces a molten pool 124 of the fin powder 122 as the laser beam 262 is scanned across the laser powder bed in the production chamber 222; in FIG. 11, as the laser beam 262 is scanning, the molten pool 124 solidifies to form a third layer 120-3 of the fin 120. For illustration, FIG. 11 shows three layers of the fin 120 being built successively, layer by layer.

The above LPBF or SLM process 200 for fabricating the heat sink 100 has many advantages over known fabrication methods. For example, as described above, the hybrid 3D printed heat sinks 100 have similar or superior cooling performance and higher temperature stability compared to the EDM wire-cut heat sink 12. The other advantages are: no post-processing is required as compared to conventional 3D printing of metal which required the fabricated part to be removed from the substrate. Without involving any subtractive manufacturing process for forming the fins 120 when compared to EDM wire-cut heat sink 12, there are savings on materials as no materials are wasted, except for subtractive machining processes for forming the substrate 140. This hybrid LPBF or SLM process 200 is also a faster process than EDM wire-cut. In addition, this hybrid LPBF or SLM process 200 is suitable for batch fabrication and higher through-put, thus making this hybrid process 200 economical or more productive to produce heat sinks 100 with fine fin geometry and fine spacings.

While specific embodiments have been described and illustrated, it is understood that many changes, modifications, variations and combinations of variations disclosed in the text description and drawings thereof could be made to the present invention without departing from the scope of the present invention. For example, two or more laser members 260 may be employed to increase the speed of the above hybrid 3D print fabrication. When the hybrid LPBF or SLM process 200 uses aluminium-based fin powder, it is possible to provide a non-oxidising environment around the production chamber 222.

1. A heat sink comprising:
a substrate; and
a plurality of fins, with a first layer of each fin being formed directly on the substrate using a laser powder-bed fusing (LPBF) or selective laser melting (SLM) process on a fin powder deposited on the substrate, wherein the plurality of fins is built up, layer by layer by laser fusion, to reach a predetermined height.

2. The heat sink according to claim 1, wherein the fin powder is selected from the following: CuCrZr, pure copper, copper alloys, aluminium or aluminium alloy.

3. The heat sink according to claim 1, wherein the substrate is machined from a material selected from the following: copper; copper alloy, aluminium or aluminium alloy.

4. The heat sink according to claim 1, wherein each of the plurality of fins has a height: thickness ratio range of substantially 4:1 to 20:1.

5. The heat sink according to claim 1, wherein each of the plurality of fins has a height: spacing ratio range of substantially 4:1 to 35:1.

6. The heat sink according to claim 1, wherein each of the plurality of fins is configured with a parallelogram cross-sectional shape or geometry.

7. The heat sink according to claim 6, wherein the plurality of fins is configured in rows, wherein a row spacing is substantially equal or greater than an oblique spacing between adjacent fins in a row.

8. The heat sink according to claim 1, further comprising a plurality of threaded holes for mounting a protective cover over or around the plurality of fins.

9. The heat sink according to claim 1, further comprising a plurality of holes for mounting the substrate to a member that requires heat dissipation.

10. A laser powder-bed fusing (LPBF) or selective laser melting (SLM) method for hybrid 3D print fabrication of a heat sink, the method comprises:
forming a substrate using subtractive machining;
forming a powder-bed of a fin powder over the substrate;
operating a laser to melt and to fuse particles of the fin powder to build a first layer of the fins directly on the substrate;
adding the fin powder to increase a height of the powder-bed, layer by layer; and
operating the laser to fuse the fin powder to build up the fins, layer by layer, until the fins reach a predetermined height.

11. The method according to claim 10, wherein operating the laser to build the fins, layer by layer, comprises generating a pattern of the fin geometry from a computer-aided design (CAD) or computer system and outputting the pattern to a scanner to direct a laser beam from the laser onto the fin powder.

12. The method according to claim 11, wherein the pattern comprises rows of the fins, with each fin forming a parallelogram shape, and adjacent fins in a row are spaced apart at an oblique side of the parallelogram.

13. A heat sink obtained by the hybrid 3D fabrication method of claim 10.
